(19) United States
(12) Patent Application Publication
(10) Pub. No.: US 2002/0072248 A1
(43) Pub. Date: Jun. 13, 2002

(54) Process of forming a low dielectric constant material

(75) Inventors: Huang-Chung Cheng, Hsinchu (TW); Cheng-Jer Yang, Taoyuan Hsien (TW); Ting-Chang Chang, Hsinchu (TW); Li-Jen Chou, Hsinchu (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: National Science Council

(21) Appl. No.: 09/847,985

(22) Filed: May 2, 2001

(30) Foreign Application Priority Data
Dec. 8, 2000 (TW) 89126238

(51) Int. Cl. H01L 21/31

(52) U.S. Cl. 438/778

(57) ABSTRACT

A process of forming a low dielectric constant (low k) material is disclosed. The process of the present invention comprises introducing silane (SiₙH₂ₙ₊₂) and fluorocarbon (CₘF₂ₘ₊₂) gases, where n=1 to 3 and m=1 to 3, into a chemical vapor deposition (CVD) chamber, thus forming a low dielectric material layer on a substrate having semiconductor devices by the CVD process. An in situ Argon annealing process is then performed in the chamber. The process of the present invention produces a layer having a dielectric constant of 2.5 and good thermal stability.

### BACKGROUND OF THE INVENTION

1. Field of the Invention

The present invention relates to semiconductor integrated circuits. In particular, the present invention relates to a process of forming a low dielectric constant (low k) material using chemical vapor deposition (CVD). It can reduce the dielectric constant and provide good thermal stability by adjusting to the reaction gas flow rate and plasma power, and perform an Argon annealing treatment.

2. Description of the Related Art

With the progress of Ultra Large Scale Integration (ULSI), integrated circuit density has increased and device sizes have become decreased. Unfortunately, as device dimensions decrease, parasitic capacitance, inherent in the intermetal dielectric (IMD) layers between the metal lines in the device of the integrated circuit has resulted in an increase in the RC delay effect, where R is the resistance of the metal line, and C is the level of parasitic capacitance. In order to reduce the RC delay effect, a low dielectric constant material is adopted, for example, fluorine-doped silicon oxide and organic polymer.

The intermetal dielectric (IMD) layer requires good thermal stability and poor moisture absorption to improve reliability. The conventional method is to deposit an oxide layer to serve as a dielectric layer by using plasma-enhanced chemical vapor deposition (PECVD) and the dielectric constant (k) is about 3.9 to 4.2. In general, SiO₂-based, Siloxane-based, SiN and ceramic materials are used for the dielectric layer. However, the dielectric constant of the materials mentioned above is usually larger than 3.0. It is necessary to use a lower dielectric constant material in the sub-micron domain thereby reducing the RC delay effect, power depletion and cross talk between adjacent metal lines in the integrated circuit.

To date, many kinds of low dielectric constant materials have been developed. They can be grouped into two types, organic and inorganic. Deposition methods are also of two types, chemical vapor deposition (CVD), and spin on glass (SOG) methods. The conventional method of chemical vapor deposition reduces the dielectric constant of silicon dioxide by doping fluorine therein. This material (Fluorinated SiO₂, SiOF) is called FSG. It can be formed by the reaction between the gases of SiF₄ and tetraethyl orthosilicate (TEOS). Its desired dielectric constant of between 3.2 and 3.6 can only be achieved with the correctly regulated amount of fluorine doping. The SOG method is a commonly used procedure in which the dielectric material contained in the solvent, having good gap filling ability, is spin-coated onto the substrate. The SOG materials, for example, the polymer of hydrogen silsesquioxane (HSQ) and methyl silsesquioxane (MSQ), since open structure by themselves, the low dielectric constant of 2.6 to 2.8 are achieved. However, SOG material easily peels off the substrate, causing an increase in leakage current in the device. Further, the thermal stability of most SOG materials is poor, thereby limiting their practical applicability.

### SUMMARY OF THE INVENTION

An object of the present invention is to provide a low dielectric constant material layer to reduce RC delay time in integrated circuits.

Another object of the present invention is to provide a low dielectric constant material layer having good thermal stability that can increase the reliability of integrated circuits.

In accordance with the objects of this invention, a process of low dielectric constant material is provided and comprises the steps of: (a) Providing a semiconductor substrate having semiconductor devices formed on the substrate; (b) Placing the substrate in a chemical vapor deposition chamber; (c) Heating the substrate in the chemical vapor deposition chamber; and (d) Providing silane (SiₙH₂ₙ₊₂) gas and fluorocarbons (CₘF₂ₘ₊₂) gas where n=1 to 3 and m=1 to 3 into the chemical vapor deposition chamber to serve as reaction gases, and then forming a low dielectric constant material layer on the substrate. An Argon annealing process is performed on the substrate after (d), wherein the annealing condition is: a temperature of 350° C., and the pressure of the Argon is between 600 and 1000 mTorr.

In addition, the dielectric layer is created, in accordance with the present invention, in which a dielectric constant of 2.5 is achieved when the flow ratio between CF₄and SiH₄is 20, the pressure of the reaction gases is 800 mTorr and the plasma power is 50 W. After Argon annealing is performed, the layer exhibits low leakage current and good thermal stability.

### BRIEF DESCRIPTION OF THE DRAWINGS

The present invention can be more fully understood by reading the subsequent detailed description in conjunction with the example and references made to the accompanying drawings, wherein:

FIG. 1 through 1B are schematic cross-sectional views showing the process of low dielectric constant material in accordance with the present invention.

FIG. 2 is a graph diagram showing the relationship between the dielectric constant and the gases flow ratio (CF₄/SiH₄) in accordance with present invention.

FIG. 3 is a graph diagram showing the relationship between the annealing time and the increment of film thickness in accordance with the present invention

### DETAILED DESCRIPTION OF THE PREFERRED EMBODIMENT

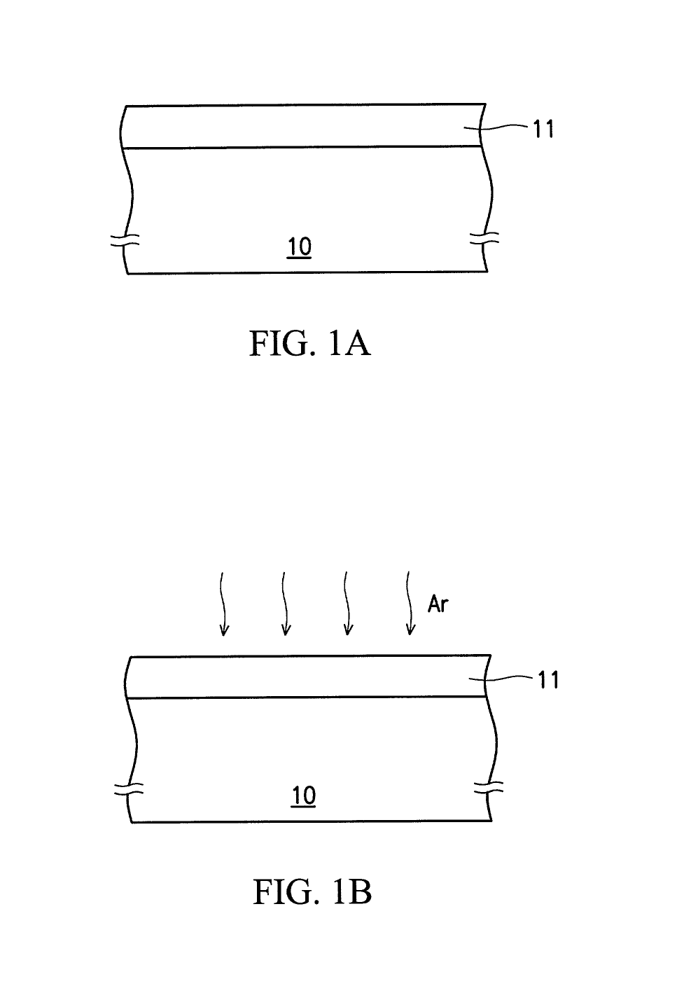

A process of forming low dielectric constant material according to the present invention is described in FIG. 1A to 1B.

First, as shown in FIG. 1A, a semiconductor substrate 10 having semiconductor devices (not shown) is disposed into a CVD chamber (not shown). Then, the semiconductor substrate 10 is heated to between 30 and 400° C., with the preferred range 300 to 400° C. and optimum temperature being 350° C. Next, the reaction gases are introduced into the chamber so as to deposit the low dielectric material layer on the substrate 10 when the base pressure in the chamber is below 1×10⁻³ Torr.

As above, silane (SiH₄) and fluorocarbon (CF₄) gases are provided to serve as reaction gases in which flow rates are controlled at 1 to 20 sccm and 100 to 1000 sccm, respectively. The flow ratio between CF₄ and SiH₄ (i.e. the gas flow rate of CF₄/the gas flow rate of SiH₄) is adjusted to about 5 to 20, with the preferred ratio being 20. Hence, the working pressure in the chamber is between 100 and 1000 mTorr. The preferred working pressure range is between 700 and 900 mTorr, with 800 mTorr the optimum.

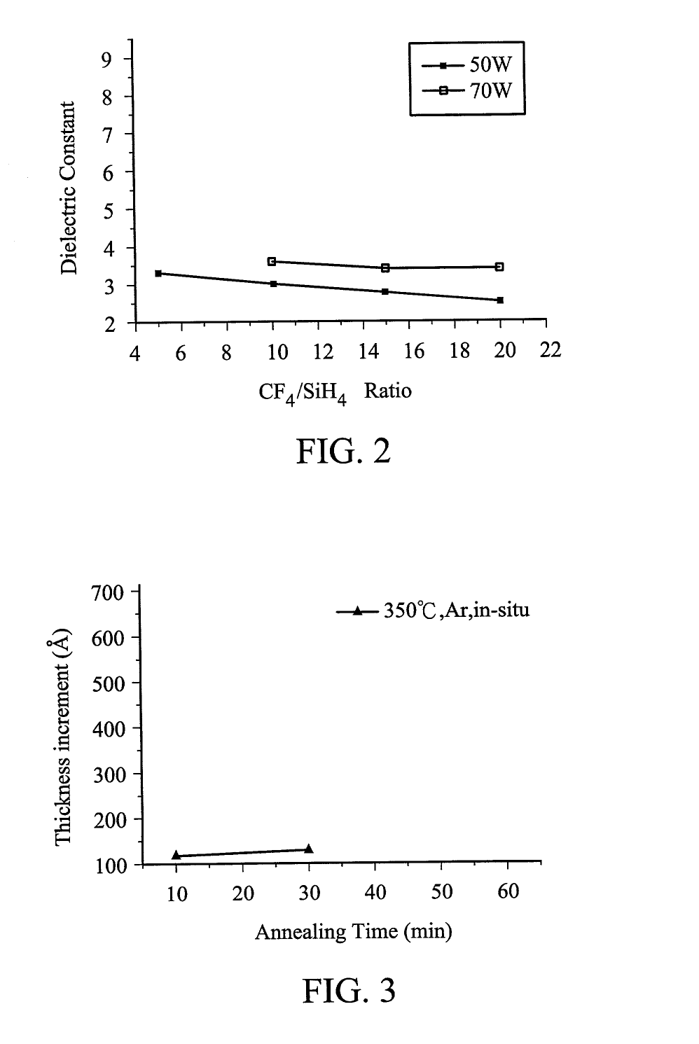

Then, a low dielectric constant material layer (SiCF) 11 is formed on the substrate 10 with the CVD method of chemical vapor deposition such as plasma-enhanced chemical vapor deposition (PECVD), electron cyclotron resonance chemical vapor deposition (ECRCVD) or inductively-coupled plasma chemical vapor deposition (ICPCVD). In this manner, the plasma power is adjusted to a range of 10 to 400 W, with a preferred range of 40 to 60 W, and optimum being 50 W. A low dielectric constant material layer 11 contains components of carbon, silicon and fluorine formed by decomposing the reaction gases by plasma. Refer to FIG. 2, which shows a graph diagram of the relationship between the flow ratio of CF₄ to SiH₄ (CF₄/SiH₄) and the dielectric constant of the layer 11 where the plasma power levels are 50 W and 70 W, respectively, in accordance with the present invention. As shown in FIG. 2, the material layer 11 has the lowest dielectric constant value (k=2.5) when the flow ratio (CF₄/SiH₄) is 20 and the plasma power is 50 W.

Refer to FIG. 1B, which shows the in situ Argon annealing process for performing the low dielectric constant material layer 11. The annealing condition consists of: a temperature between 200° C. and 350° C., with a preferred temperature of 350° C.; flow rate of the Argon between 100 and 500 sccm; pressure of the Argon between 600 and 1000 mTorr. Thereafter, to measure the leakage current of the layer 11 and as the result, the leakage current of the layer 11 is less than 10 nA /cm². Refer to FIG. 3, which shows a graph diagram of the relationship between the annealing time and the increment of film thickness at a temperature of 350° C. As shown in FIG. 3, after performing an in situ Argon annealing to the layer 11 in the chamber at a temperature of 350° C., the incremental thickness of the layer 11 is small. That is, it is provided a good thermal stability.

Therefore, the process of low dielectric constant material in accordance with the present invention provides a low dielectric constant (k=2.5), small leakage current and good thermal stability. Moreover, the process as obtained in accordance with the present invention can be used in existing equipment for manufacturing semiconductor devices.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

what is claimed is:

1. A process of forming a low dielectric constant material comprises the steps of:
(a) Providing a semiconductor substrate with semiconductor devices formed on the substrate;
(b) Placing the substrate in a chemical vapor deposition chamber;
(c) Heating the substrate in the chemical vapor deposition chamber; and
(d) Providing silane (SiₙH₂ₙ₊₂) gas and fluorocarbons (CₘF₂ₘ₊₂) gas where n=1 to 3 and m=1 to 3 into the chemical vapor deposition chamber to serve as reaction gases, and then forming a low dielectric constant material layer on the substrate.

2. The process as claimed in claim 1, wherein the heating temperature of the substrate is 30° C. to 400° C.

3. The process as claimed in claim 1, wherein the heating temperature of the substrate is 300° C. to 400° C.

4. The process as claimed in claim 1, wherein the silane is SiH₄, and the fluorocarbon is CF₄.

5. The process as claimed in claim 1, wherein the chemical vapor deposition comprises a plasma-enhanced chemical vapor deposition (PECVD), electron cyclotron resonance chemical vapor deposition (ECRCVD) and inductively-coupled plasma chemical vapor deposition (ICPCVD).

6. The process as claimed in claim 1, wherein the low dielectric material layer contains the elements of carbon, silicon and fluorine (SiCF).

7. The process as claimed in claim 4, wherein the flow rates of the SiH₄ and the CF₄ are about 1 to 20 sccm and 100 to 1000 scam, respectively.

8. The process as claimed in claim 4, wherein the ratio of the gas flow rate between the CF₄ and the SiH₄ is about 5 to 20.

9. The process as claimed in claim 4, wherein the pressure of the reacting gases is about 100 to 1000 mTorr.

10. The process as claimed in claim 4, wherein the pressure of the reaction gases is about 700 to 900 mTorr.

11. The process as claimed in claim 4, wherein the plasma power of the chemical vapor deposition is about 10 to 400 W.

12. The process as claimed in claim 4, wherein the plasma power of the chemical vapor deposition is about 40 to 60 W.

13. The process as claimed in claim 1, further comprising an Argon annealing process after step (d).

14. The process as claimed in claim 13, wherein the annealing temperature is 200° C. to 350° C.

15. The process as claimed in claim 13, wherein the f low rate of the Argon is 100 to 500 sccm.

16. The process as claimed in claim 13, wherein the pressure of the Argon is 600 to 1000 mTorr.
